(19) United States
(12) Patent Application Publication
(10) Pub. No.: US 2017/0164529 A1
(43) Pub. Date: Jun. 8, 2017

(54) ELECTROMAGNETIC SHIELDING LOCK BOX

(71) Applicant: Yao-Kun Yang, CHANGHUA COUNTY (TW)

(72) Inventor: Yao-Kun Yang, CHANGHUA COUNTY (TW)

(21) Appl. No.: 14/963,188

(22) Filed: Dec. 8, 2015

(51) Int. Cl. H05K 9/00; E05B 67/38; E05B 37/00; E05B 17/22; E05B 19/00; E05B 17/00; E05B 67/02

(52) U.S. Cl. CPC H05K 9/0084; H05K 9/0045; E05B 17/0075; E05B 67/38; E05B 67/02; E05B 17/22; E05B 19/0082; E05B 19/0005; E05B 37/0068

(57) ABSTRACT

An electromagnetic shielding lock box comprises an openable and closable box body. The box body is defined an accommodating groove, made by electromagnetic shielding materials, and has a lock unit and a hooking member. The box body is closed for receiving at least one key while the lock unit is in a locking status and for shielding the transmission of at least one electromagnetic wave signal due to the electromagnetic shielding materials. The lock unit is further limited the hooking member to be locked to the box body. The box body is opened for taking the at least one key out while the lock unit is in an unlocking status to unlock the hooking member from the box body.

### BACKGROUND OF THE INVENTION

1. Field of the Invention

The present invention relates to an electromagnetic shielding lock box, and especially relates to a lock box capable for shielding electromagnetic wave signals.

2. Description of Related Art

In the light of the development of technologies, the life quality for people is requested higher and higher. In order to satisfy people's demands, many convenient products are developed by relative vendors.

For example, the conventional metal key is cooperated with a lock to secure the door(s) or electric switch(es) of a car, but the conventional metal key is easy to be duplicated or damaged and hard to prevent thieves. After the electric technology is introduced into the vehicle theft security system, the main method is using double or multiple electronic locks to lock or unlock the door(s) or electric switch(es) of the car(or vehicle). For convenience, the remote control lock which uses the wireless skills may extend the transmission distance and also provide the characteristics of car searching and door(s)/electric switch(es) locking/unlocking. However, the theft security skills of the key with remote control chip are mostly cooperated with the conventional metal key to form a double security mechanism. In order to make functions perfect and integrate more functions, many famous dealers are phased in RFID (Radio Frequency IDentification) skill. It may resolve the legal identification of the key and reinforce it because the RFID key is not easy to be cracked and duplicated. Evenly the portable key may be integrated with additional applications, such as micro-payments and the electronic purse.

However, although RFID start-up system without key makes life more convenient due to fast growing technology, the electromagnetic wave signals emitted from the portable I-KEY remote control key are really caused physical injuries continuously.

In view of the foregoing circumstances, the inventor has invested a lot of time to study the relevant knowledge, compare the pros and cons, research and develop related products. After quite many experiments and tests, the “electromagnetic shielding lock box” of this invention is eventually launched to improve the foregoing shortcomings, to meet the public use.

### SUMMARY OF THE INVENTION

The main object of this invention is providing an electromagnetic shielding lock box for shielding the electromagnetic wave signals emitted from at least one key (such as I-KEY remote control key) which has the RFID system.

In order to achieve above mentioned object, an electromagnetic shielding lock box comprises an openable and closable box body, defined an accommodating groove, the box body is made by electromagnetic materials and has a lock unit and a hooking member, the box body is closed for receiving at least one key while the lock unit is in a locking status and for shielding the transmission of at least one electromagnetic wave signal due to the electromagnetic shielding materials, the lock unit is further limited the hooking member to be locked to the box body, and the box body is opened for taking the at least one key out while the lock unit is in an unlocking status to unlock the hooking member from the box body.

In some embodiments, the hooking member has an assembling end and a free end opposite to the assembling end, the assembling end is passing through and assembled to the box body, and the free end is locked to or unlocked from the box body. In some embodiments, the electromagnetic shielding materials are Graphene or Binchotan charcoal.

An electromagnetic shielding lock box is further provided and comprises an openable and closable box body, defined an accommodating groove and having a lock unit and a hooking member, the box body is closed while the lock unit is in a locking status, the lock unit is further limited the hooking member to be locked to the box body, and the box body is opened while the lock unit is in an unlocking status to unlock the hooking member from the box body; and an accommodating member, arranged in the accommodating groove, the accommodating member has two cases capable for being assembled or disassembled relative to each other, the two cases are made by electromagnetic shielding materials, and the two cases are defined a receiving groove for receiving at least one key.

In some embodiments, the hooking member has an assembling end and a free end opposite to the assembling end, the assembling end is passing through and assembled to the box body, and the free end is locked to or unlocked from the box body.

In some embodiments, the electromagnetic shielding materials are Graphene or Binchotan charcoal.

The various objects and advantages of the present invention will be more readily understood from the following detailed description when read in conjunction with the appended drawing.

### BRIEF DESCRIPTION OF THE DRAWINGS

FIG. 1 is a perspective view of a s electromagnetic shielding lock box of the present invention while the box body is opened;

FIG. 2 is a perspective view of an accommodating groove of the electromagnetic shielding lock box of the present invention while accommodating keys;

FIG. 3 is a perspective view of the box body of the electromagnetic shielding lock box of the present invention while being assembled to each other and arranging keys;

FIG. 4 is a perspective view of the electromagnetic shielding lock box of the present invention while a hooking member is locked to a handlebar;

FIG. 5 is a perspective view of another embodiment of the hooking member of the electromagnetic shielding lock box of the present invention;

FIG. 6 is a perspective view of the electromagnetic shielding lock box of the present invention while the hooking member is locked to a spoke of a rim;

FIG. 7 is an exploded view of another embodiment of the electromagnetic shielding lock box of the present invention; and

FIG. 8 is an perspective view of another embodiment of the electromagnetic shielding lock box of the present invention.

### DETAILED DESCRIPTION OF THE INVENTION

To describe clearly that the present invention achieves the foregoing object and function, the technical features and desired function are described with reference to a preferred embodiment and accompanying drawings.

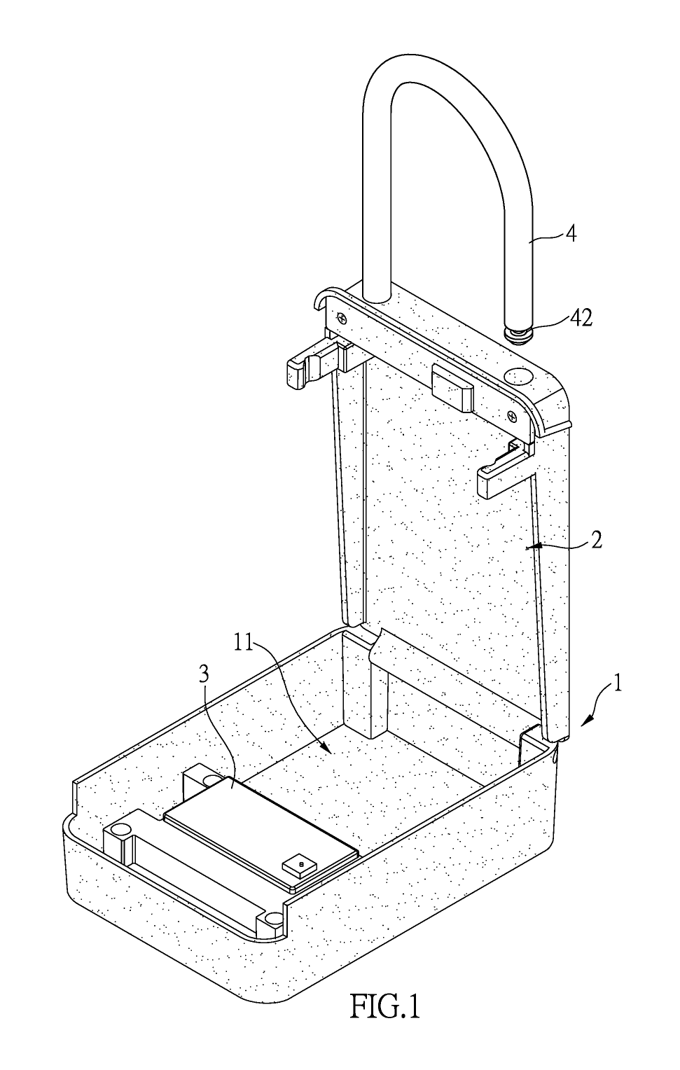

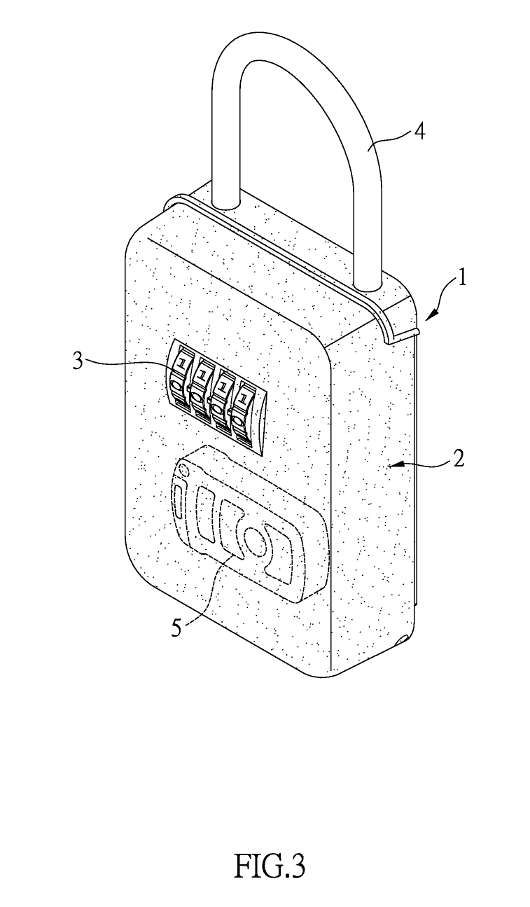

Please reference to FIGS. 1-3, an electromagnetic shielding lock box of the present invention of the present invention may comprise an openable and closable box body 1. The box body 1 is defined an accommodating groove 11. The box body 1 is made by electromagnetic materials 2 and has a lock unit 3 and a hooking member 4. The box body 1 is closed for receiving keys (or a key) 5 while the lock unit 3 is in a locking status and for shielding the transmission of at least one electromagnetic wave signal due to the electromagnetic shielding materials 2. The lock unit 3 is further limited the hooking member to be locked to the box body 1. And the box body 1 is opened for taking the keys (or a key) 5 out while the lock unit 3 is in an unlocking status to unlock the hooking member 4 from the box body 1.

The above mentioned embodiment is the main skill feature of this invention and corresponds to the claim 1 of this invention to understand the object and embodiments of this invention in detail. And the skill features of the depending claims are for describing the claim 1 in detail or adding more skill features, but not limited thereto. It should be known that the claim 1 is not necessary to include the skill features of the depending claims.

According to above mentioned structure, because the recent social trends, most of cars have equipped with I-KEY remote control key 5 with RFID system for controlling the doors or electric switches of the car to start up or shut down. Therefore, after parking and closing the door or electric switch, the lock unit 3 is unlocked to open the box body 1 and then putting the I-KEY remote control key 5 in the accommodating groove 11 of the box body 1. After locking the lock unit 3 to close the box body 1, the transmission of the electromagnetic wave signals emitted from the I-KEY remote control key 5 arranged in the accommodating groove 11 of the box body 1 is shielded by the box body 1 made by the electromagnetic materials so that a receiver arranged in the car may not receive the electromagnetic signals emitted from the I-KEY remote control key 5. The I-KEY remote control key 5 is not necessary to be carried with the driver (or an user) to prevent the electromagnetic wave signals emitted from the I-KEY remote control key 5 from causing physical injuries continuously. The driver (or user) may not worry that the box body 1 and the door or electric switch of the car are opened by others because of the box body 1 made by the electromagnetic shielding materials and the arrangement of the lock unit 3. When the driver (or the user) comes back to drive the car, the lock unit 3 is unlocked and then the hooking member 4 is released to make the box body 1 disassemble from the locking position so that the box body 1 is opened and the I-KEY remoter control key 5 arranged in the accommodating groove 11 may be taken out.

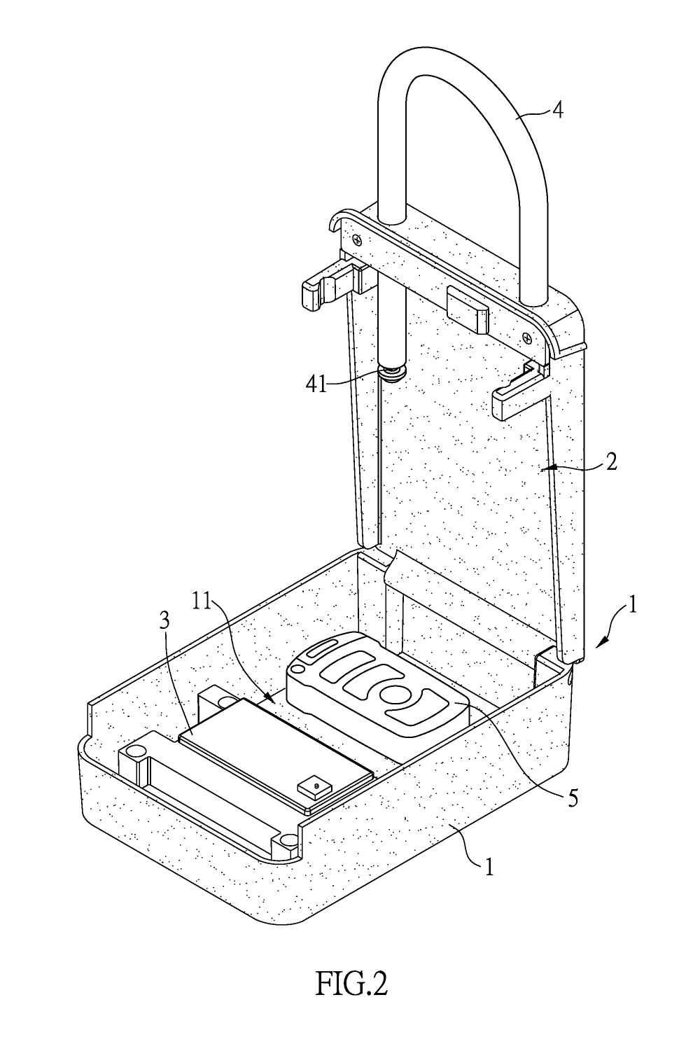

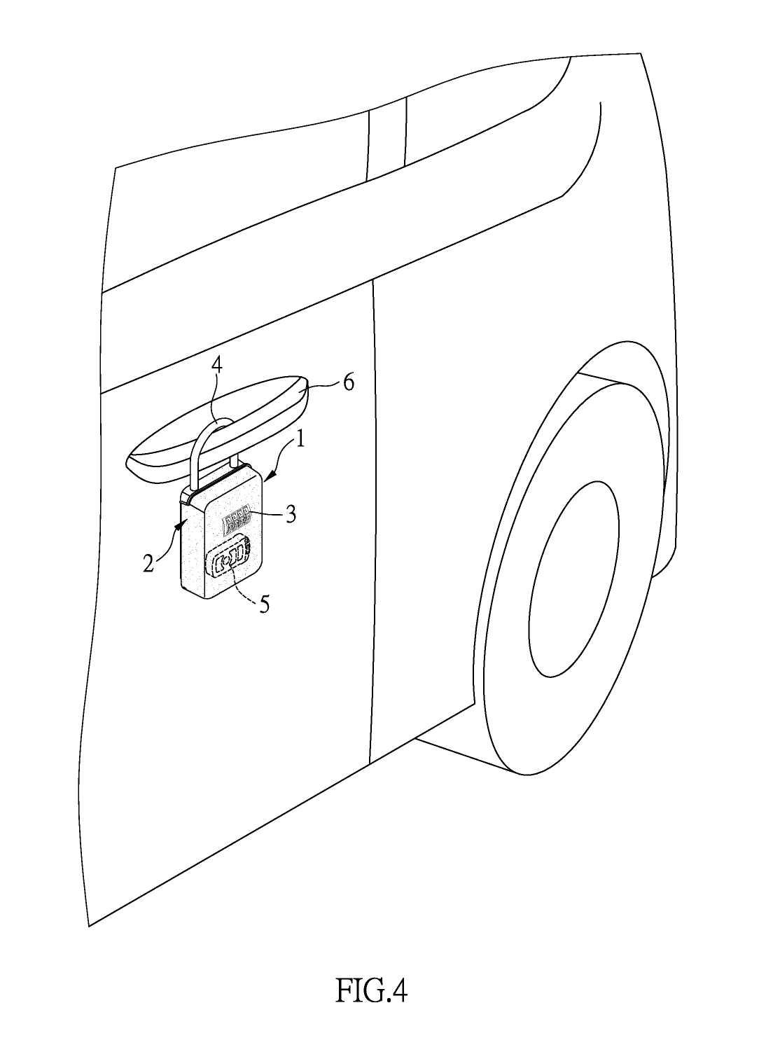

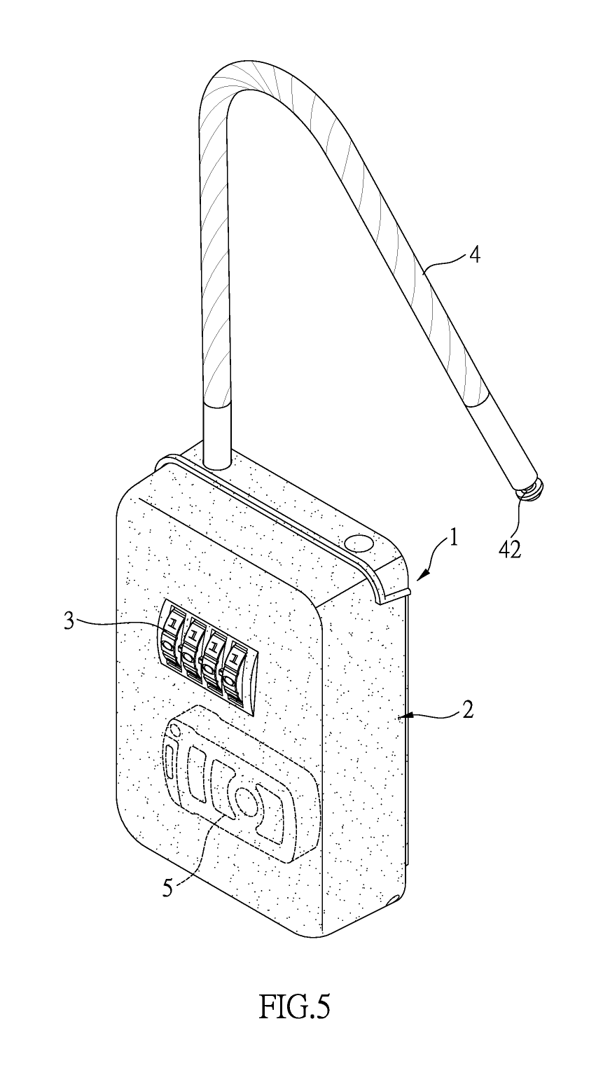

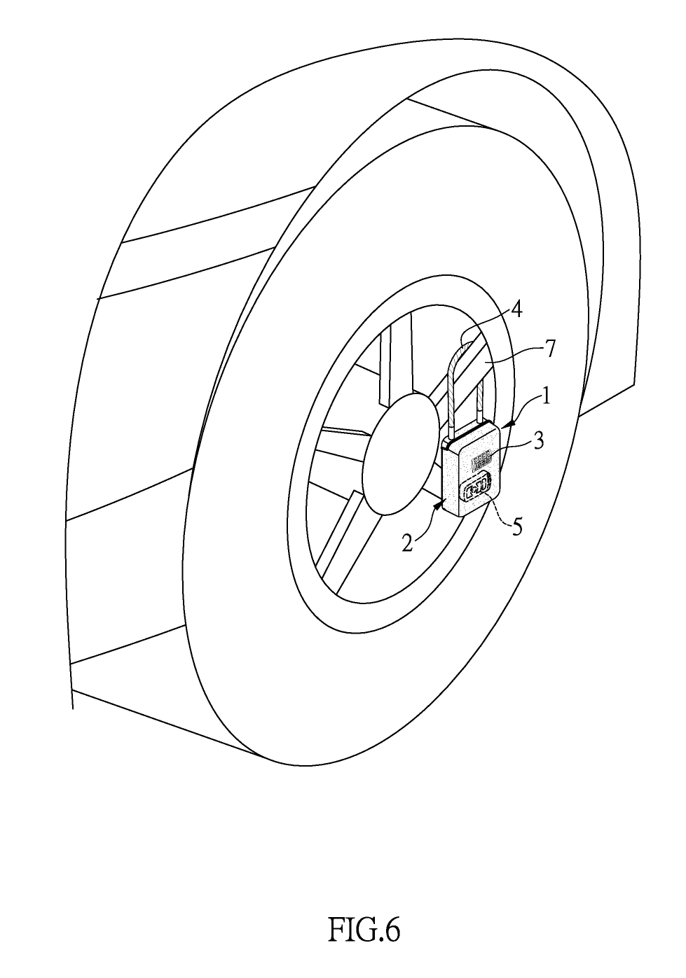

Please refer to FIGS. 1 and 2, the hooking member 4 has an assembling end 41 and a free end 42 opposite to the assembling end 41. The assembling end 41 is passing through and assembled to the box body 1 and the free end 42 is locked to or unlocked from the box body 1. In FIGS. 1 and 2, the hooking member 4 is inverted U-shaped. When the lock box of the present invention is locked to a handlebar 6 of the car, the inverted U-shaped free end 42 may be passed through the handlebar 6 and locked to the box body 1 (shown as in FIG. 4). Please refer to FIG. 5, the hooking member 4 may be a metal steel cable. When the lock box of the present invention is locked to the spoke 7 of a rim, the free end 42 of the hooking member 4 which is the metal steel cable may be passed through the spoke 7 of the rim and locked to the box body 1 (shown as in FIG. 6) due to the flexibility of the metal steel cable.

Please refer to FIG. 1, the electromagnetic shielding materials 2 may be Graphene or Binchotan charcoal. The embodiment of FIG. 1 is that the electromagnetic shielding materials 2 are mixed with or coated on the box body 1 for providing the box body 1 to have the electromagnetic shielding effect.

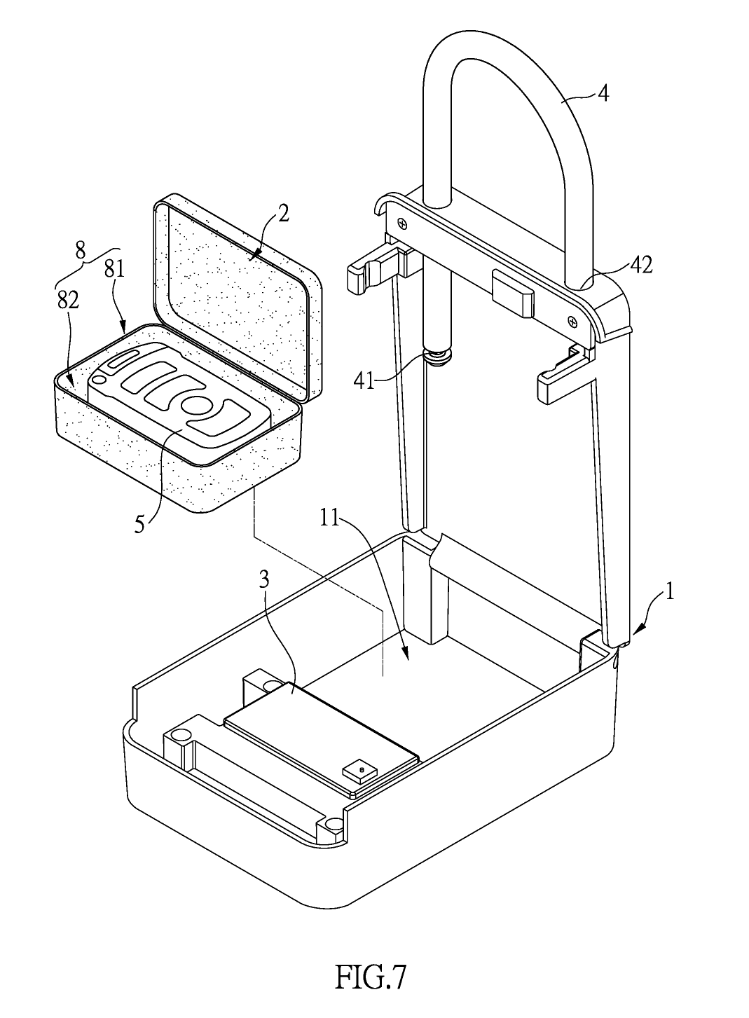

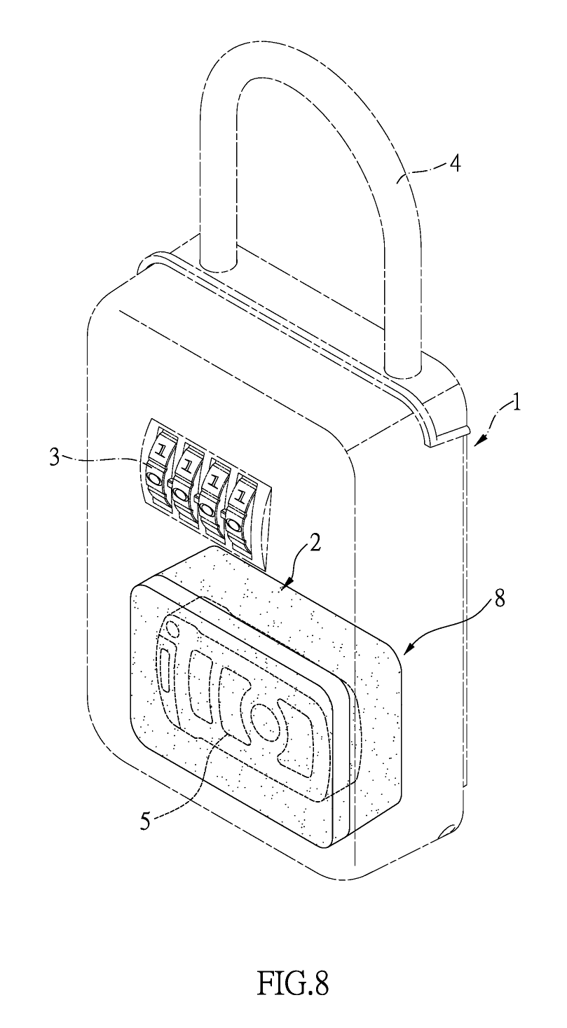

Please refer to FIGS. 7 and 8, another embodiment of the electromagnetic shielding lock box of the present invention may comprise an openable and closable box body 1 and an accommodating member 8. The box body 1 may be defined an accommodating groove 11 and have a lock unit 3 and a hooking member 4. The box body 1 is closed while the lock unit 3 is in a locking status. The lock unit 3 is further limited the hooking member 4 to be locked to the box body 1. And the box body 1 is opened while the lock unit 3 is in an unlocking status to unlock the hooking member 4 from the box body 1. The accommodating member 8 is arranged in the accommodating groove 11 of the box body 1. The accommodating member 8 has two cases 81 which are capable for being assembled or disassembled relative to each other. The two cases 81 are made by electromagnetic shielding materials 2. And the two cases 81 are defined a receiving groove 82 for receiving at least one key 5.

Therefore, after parking and closing the door or electric switch of the car, the I-KEY remote control key 5 may be put in the receiving groove 82 of the accommodating member 8 which is mixed with or coated the electromagnetic shielding materials 2 for shielding the electromagnetic wave signals and then the accommodating member 8 is put in the accommodating groove 11 of the box body 1 so that the lock unit 3 and the hooking member 4 may be locked the box body 1 to the handlebar 9 or the spoke 7. The I-KEY remote control key 5 may be not carried with the driver (or the user) to prevent the electromagnetic wave signals emitted from the I-KEY remote control key 5 continuously from causing physical injuries.

The foregoing descriptions are merely the exemplified embodiments of the present invention, where the scope of the claim of the present invention is not intended to be limited by the embodiments. Any equivalent embodiments or modifications without departing from the spirit and scope of the present invention are therefore intended to be embraced.

The disclosed structure of the invention has not appeared in the prior art and features efficacy better than the prior structure which is construed to be a novel and creative invention, thereby filing the present application herein subject to the patent law.

1. An electromagnetic shielding lock box, comprising:
an openable and closable box body, defined an accommodating groove, the box body is made by electromagnetic shielding materials and has a lock unit and a hooking member, the box body is closed for receiving at least one key while the lock unit is in a locking status and for shielding the transmission of at least one electromagnetic wave signal due to the electromagnetic shielding materials, the lock unit is further limited the hooking member to be locked to the box body, and the box body is opened for taking the at least one key out while the lock unit is in an unlocking status to unlock the hooking member from the box body;
wherein the hooking member has an assembling end and a free end opposite to the assembling end, the assembling end is passing through and assembled to the box body, and the free end is locked to or unlocked from the box body; and
wherein the electromagnetic shielding materials are Graphene or Binchotan charcoal.

2. (canceled)

3. (canceled).

4. An electromagnetic shielding lock box, comprising:
an openable and closable box body, defined an accommodating groove and having a lock unit and a hooking member, the box body made by electromagnetic shielding materials is closed while the lock unit is in a locking status, the lock unit is further limited the hooking member to be locked to the box body, and the box body is opened while the lock unit is in an unlocking status to unlock the hooking member from the box body; and
an accommodating member, arranged in the accommodating groove, the accommodating member has two cases capable for being assembled or disassembled relative to each other, the two cases are made by electromagnetic shielding materials, and the two cases are defined a receiving groove for receiving at least one key;
wherein the hooking member has an assembling end and a free end opposite to the assembling end, the assembling end is passing through and assembled to the box body, and the free end is locked to or unlocked from the box body; and
wherein the electromagnetic shielding materials are Graphene or Binchotan charcoal.

5. (canceled)

6. (canceled)
